(19) United States
(12) Patent Application Publication
(10) Pub. No.: US 2026/0198320 A1
(43) Pub. Date: Jul. 9, 2026

(54) COMPOSITE PACKAGE AND METHODS FOR FORMING THE SAME

(71) Applicant: Taiwan Semiconductor Manufacturing Company Limited, Hsinchu (TW)

(72) Inventors: Yu-Chen Hu, Hsinchu City (TW); Wei-Chih Chen, Taipei City (TW); Hao-Cheng Hou, Hsinchu City (TW); Po-Han Wang, Hsinchu City (TW); Yu-Min Liang, Zhongli City (TW); Wei-An Tsao, Yuanlin Township (TW); Hao-Yi Tsai, Hsinchu City (TW); Hung-Jui Kuo, Hsinchu (TW)

(21) Appl. No.: 19/008,954

(22) Filed: Jan. 3, 2025

(51) Int. Cl. H01L 23/00; H01L 21/306; H01L 23/498; H01L 23/538; H01L 25/16; H05K 1/18; H10B 80/00; H10D 80/30

(52) U.S. Cl. CPC H10W 42/00; H10P 50/644; H10W 70/65; H05K 1/181; H10B 80/00; H10D 80/30; H10W 70/611; H10W 70/685; H10W 72/0198; H10W 72/07236; H10W 72/248; H10W 72/334; H10W 74/15; H10W 90/00; H10W 90/401; H10W 90/724; H10W 90/734

(57) ABSTRACT

A semiconductor structure that suppresses moisture-induced delamination may be provided by forming an interposer including first redistribution wiring interconnects embedded within first redistribution dielectric layers; forming die-side bump structures and dummy bump structures on a respective one of the first redistribution wiring interconnects; and attaching at least one semiconductor die including a respective array of on-die bump structures to a respective subset of the die-side bump structures of the interposer. The dummy bump structures are not bonded to any of the at least one semiconductor die due to a vertical gap between the dummy bump structures and the at least one semiconductor die.

### BACKGROUND

Redistribution structures and microbump structures are commonly used in advanced packaging technologies to interconnect various components within a semiconductor package. However, moisture-induced stress around the redistribution dielectric structures and microbump structures may lead to delamination and cracking during thermal processes, compromising the reliability and yield of the semiconductor package.

### BRIEF DESCRIPTION OF THE DRAWINGS

Aspects of the present disclosure are best understood from the following detailed description when read with the accompanying figures. It is noted that, in accordance with the standard practice in the industry, various elements are not drawn to scale. In fact, the dimensions of the various elements may be arbitrarily increased or reduced for clarity of discussion.

FIG. 1 is a top-down view of a first carrier wafer according to an embodiment of the present disclosure.

FIG. 2 is a vertical cross-sectional view of a unit area of an intermediate structure including the first carrier wafer after attachment of through interposer via structures according to an embodiment of the present disclosure.

FIG. 3 is vertical cross-sectional view of the intermediate structure after attachment of local silicon interconnect dies according to an embodiment of the present disclosure.

FIG. 4 is a schematic vertical cross-sectional view of a local silicon interconnect die.

FIG. 5 is a vertical cross-sectional view of the intermediate structure after formation of a first molding compound matrix according to an embodiment of the present disclosure.

FIG. 6 is a vertical cross-sectional view of the intermediate structure after formation of a first subset of first redistribution wiring interconnects and a first subset of first redistribution dielectric layers according to an embodiment of the present disclosure.

FIG. 7 is a vertical cross-sectional view of the intermediate structure after formation of a second subset of the first redistribution wiring interconnects and a second subset of the first redistribution dielectric layers according to an embodiment of the present disclosure.

FIG. 8 is a vertical cross-sectional view of the intermediate structure after formation of discrete openings through a topmost first redistribution dielectric layer according to an embodiment of the present disclosure.

FIG. 9A is a vertical cross-sectional view of the intermediate structure after formation of die-side bump structures, dummy bump structures, solder material portions, and dummy solder material portions according to an embodiment of the present disclosure.

FIG. 9B is a first exemplary layout for the second subset of the first redistribution wiring interconnects, the die-side bump structures, and the dummy bump structures according to an embodiment of the present disclosure.

FIG. 9C is a second exemplary layout for the second subset of the first redistribution wiring interconnects, the die-side bump structures, and the dummy bump structures according to an embodiment of the present disclosure.

FIGS. 9D, 9E, and 9F illustrate elements that may be used for the second subset of the first redistribution wiring interconnects according to an embodiment of the present disclosure.

FIG. 10A is a vertical cross-sectional view of the intermediate structure after attaching semiconductor dies to the interposer within each unit area according to an embodiment of the present disclosure.

FIG. 10B is a top-down view of the unit area for the intermediate structure of FIG. 10A.

FIG. 11 is a vertical cross-sectional view of the intermediate structure after formation of a second molding compound matrix according to an embodiment of the present disclosure.

FIG. 12 is a vertical cross-sectional view of the intermediate structure after attaching a second carrier wafer to a redistribution wafer according to an embodiment of the present disclosure.

FIG. 13 is a vertical cross-sectional view of the intermediate structure after detaching the first carrier wafer according to an embodiment of the present disclosure.

FIG. 14 is a vertical cross-sectional view of the intermediate structure after formation of second redistribution wiring interconnects embedded within second redistribution dielectric layers, substrate-side bump structures, and substrate-side solder material portions according to an embodiment of the present disclosure.

FIG. 15 is a vertical cross-sectional view of a composite package formed by detaching the second carrier wafer from the redistribution wafer and by dicing the redistribution wafer according to an embodiment of the present disclosure.

FIG. 16 is a vertical cross-sectional view of a semiconductor package formed by attaching a packaging substrate to the composite package according to an embodiment of the present disclosure.

FIG. 17 is a vertical cross-sectional view of a semiconductor structure formed by attaching the semiconductor package to a printed circuit board according to an embodiment of the present disclosure.

FIG. 18 is a first flowchart illustrating steps for forming a semiconductor structure according to an embodiment of the present disclosure.

FIG. 19 is a second flowchart illustrating steps for forming a semiconductor structure according to an embodiment of the present disclosure.

### DETAILED DESCRIPTION

The following disclosure provides many different embodiments, or examples, for implementing various elements of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. All elements of an original embodiment are presumed to be present in any derived embodiment unless expressly disclosed otherwise. Thus, elements described with reference to related embodiments in the drawings and/or in the specification provide support for elements in an embodiment. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe geometrical features among elements as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Embodiments of the present disclosure relate to semiconductor structures, particularly to a semiconductor structure comprising an interposer and at least one semiconductor die. The interposer includes redistribution wiring interconnects formed within redistribution dielectric layers, die-side bump structures (also referred to as first bump structures), and dummy bump structures. The redistribution wiring interconnects may include elements for mitigating against delamination such as through holes, acute angles between line segments, fine line structures or fine array structures. The redistribution dielectric layers may comprise additional elements for mitigating against delamination such as vertically-extending openings that may be subsequently filled with downward-protruding portions of an underfill material. The die-side bump structures (also referred to as first bump structures) face at least one semiconductor die, and may be used to provide solder-mediated bonding between the interposer and the at least one semiconductor die. The dummy bump structures may be formed concurrently with the die-side bump structures, and mitigate against the effect of moisture absorption by enhancing mechanical stability of the interposer.

The redistribution dielectric layers generally include polymer materials that enhance moisture absorption, while adjacent material portions such as molding compound materials and/or an underfill material layer may be resistant to moisture absorption. The difference in the propensity to absorb moisture may provide a mechanism for delamination at interfaces between different types of materials. According to an aspect of the present disclosure, delamination-resistant redistribution layer patterns and degassing-conducive structures mitigate against the risk of delamination or cracking at material interfaces between a moisture-absorbing polymer material and a moisture-absorption-resistant polymer and/or metal material. In some embodiments, an underfill material may fill openings in an upper layer of the redistribution dielectric layers. Dummy solder material portions provided on the dummy bump structures do not contact any semiconductor die. Various aspects of embodiments of the present disclosure are described with reference to the accompanying figures.

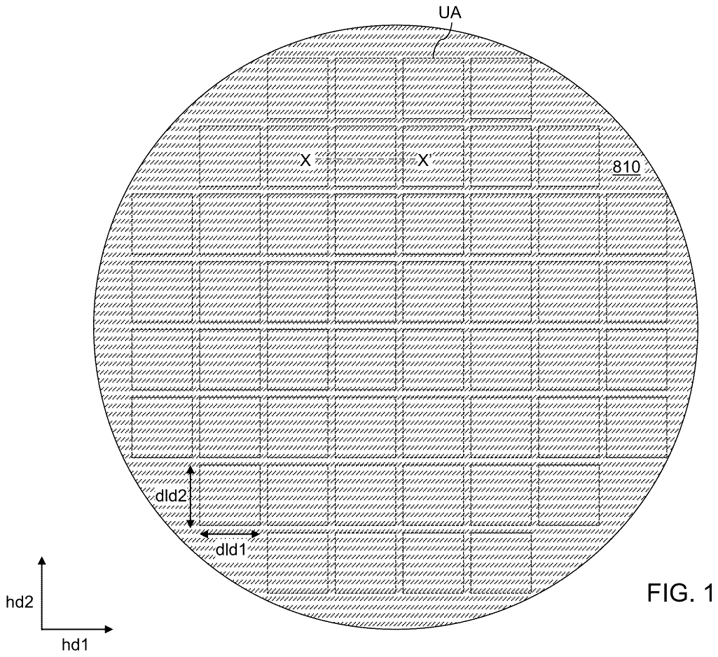

Referring to FIG. 1, a top-down view of a first carrier wafer 810 is illustrated. The first carrier wafer 810 may be any suitable planar structure for forming a reconstituted wafer thereupon. For example, the first carrier wafer 810 may comprise a silicon wafer, a glass substrate, or any other suitable substrate having a planar top surface. The first carrier wafer 810 may include an optically transparent substrate such as a glass substrate or a sapphire substrate, or may comprise a semiconductor substrate such as a silicon substrate. The lateral dimensions (such as a diameter) of the first carrier wafer 810 may be in a range from 150 mm to 450 mm, although lesser and greater diameters may be used. The thickness of the first carrier wafer 810 may be in a range from 500 microns to 2,000 microns, although lesser and greater thicknesses may also be used. Alternatively, the first carrier wafer 810 may be provided in a rectangular panel format. The first carrier wafer 810 may be large enough to contain a two-dimensional array of unit areas UA.

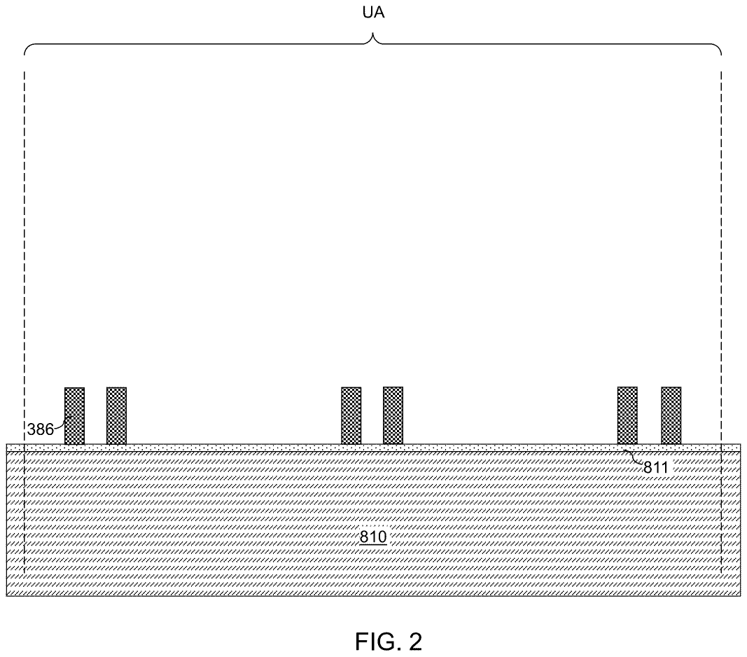

Referring to FIG. 2, a unit area UA of an intermediate structure including the first carrier wafer 810 is illustrated along a vertical plane that corresponds to the vertical plane X-X′ in FIG. 1. A first adhesive layer 811 may be applied to a front-side surface of the first carrier wafer 810. In one embodiment, the first adhesive layer 811 may be a light-to-heat conversion (LTHC) layer. Alternatively, the first adhesive layer 811 may include a thermally decomposing adhesive material.

A two-dimensional repetition of a unit via assembly may be formed over a first carrier wafer 810. Each instance of the unit via assembly may be formed within a respective unit area UA having a rectangular area. Multiple instances of the unit via assembly may be repeated along a first horizontal direction hd1 and along a second horizontal direction hd2 that is perpendicular to the first horizontal direction hd1. The unit area UA corresponds to the area of an interposer die to be subsequently formed. For example, each unit area UA may have a rectangular shape having a first side length along the first horizontal direction hd1 and having a second side length along the second horizontal direction hd2. The first side length may be the length of a pair of first sides of the rectangular shape. The second side length may be the length of a pair of second sides of the rectangular shape. The first side length is herein referred to as a first die lateral dimension dld1. The second side length is herein referred to as a second die lateral dimension dld2. Each of the first die lateral dimension dld1 and the second die lateral dimension dld2 may be independently in a range from 800 microns to 6 cm, although lesser and greater dimensions may also be used.

Each instance of the unit via assembly may be formed within a respective unit area UA of repetition, and comprises a respective set of through interposer via (TIV) structures 386. The TIV structures 386 may be conductive via structures that provide vertical electrical connections within an interposer, i.e., an interposer that includes redistribution structures that provide a fan-out configuration such that bonding pads on one side of the interposer and bonding pads on another side of the interposer have different pitches.

In one embodiment, a sacrificial matrix layer (not shown) may be formed over the first adhesive layer 811. The sacrificial matrix layer comprises a sacrificial material such as amorphous carbon, diamond-like carbon (DLC), a semiconductor material (such as amorphous silicon or a silicon-germanium alloy), or a dielectric material such as silicate glass or organosilicate glass. The thickness of the sacrificial matrix layer may be in a range from 8 microns to 60 microns, although lesser and greater thicknesses may also be used. A photoresist layer (not shown) may be applied over the sacrificial matrix layer. The photoresist layer may be lithographically pattered to form openings having a same pattern as the TIV structures 386 to be subsequently formed in a top-down view. An anisotropic etch process may be formed to transfer the pattern of the openings in the photoresist layer. Cylinder cavities may be formed through the sacrificial matrix layer underneath the openings in the photoresist layer. The photoresist layer may be removed for example, by ashing. At least one conductive material, such as at least one metallic material, may be deposited in the cylindrical cavities. For example, the at least one conductive material may comprise a conductive metallic barrier material (such as TiN, TaN, WN, or MoN) and a metallic fill material (such as W, Ti, Ta, Mo, Ru, Co, etc.). Excess portions of the at least one conductive material may be removed from above the horizontal plate including the sacrificial matrix layer. Remaining portions of the at least one conductive material that fill the cylindrical cavities comprise the TIV structures 386. Subsequently, the sacrificial matrix layer may be removed selectively to the TIV structures 386.

In another embodiment, at least one conductive material layer may be deposited as a blanket material layer, i.e., as an un-patterned material layer having a uniform thickness throughout. For example, the at least one conductive material layer may comprise a conductive metallic barrier material (such as TiN, TaN, WN, or MoN) and a metallic fill material (such as W, Ti, Ta, Mo, Ru, Co, etc.). The thickness of the at least one conductive material layer may be in a range from 8 microns to 60 microns, although lesser and greater thicknesses may also be used. A photoresist layer (not shown) may be applied over the at least one conductive material layer. The photoresist layer may be lithographically pattered to form discrete photoresist material portions having a same pattern as the TIV structures 386 to be subsequently formed in a top-down view. An anisotropic etch process may be formed to transfer the pattern of the discrete photoresist material portions through the at least one conductive material layer. Patterned portions of the at least one conductive material layer comprise the TIV structures 386.

Alternatively, the TIV structures 386 may be disposed on the first adhesive layer 811 using a pick-and-placement tool. In one embodiment a plurality of TIV structures 386, and/or an entire set of TIV structures 386 within a unit area UA, may be transferred over the first carrier wafer 810 simultaneously.

In a further alternative embodiment, the TIV structures 386 may be formed on another carrier wafer, and may be attached to the top surface of the first adhesive layer 811. The TIV structures 386 may be subsequently detached from the additional carrier wafer.

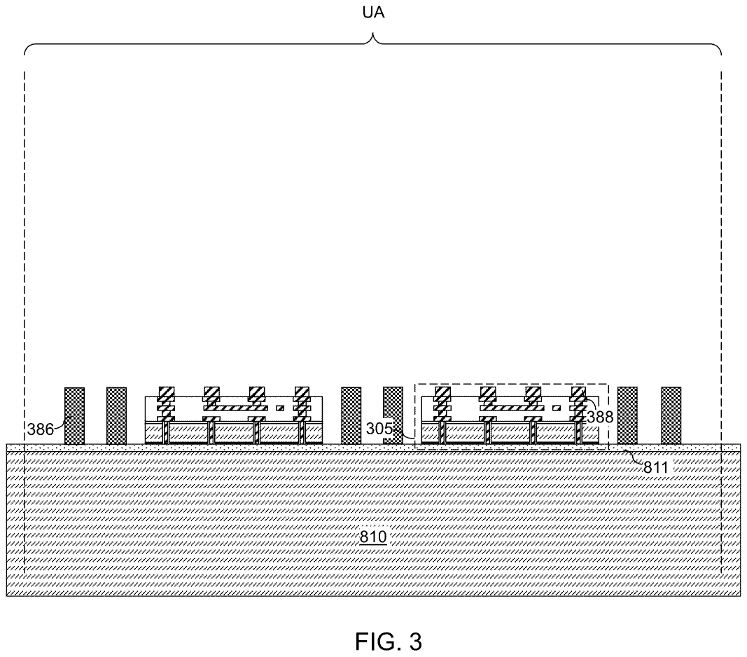

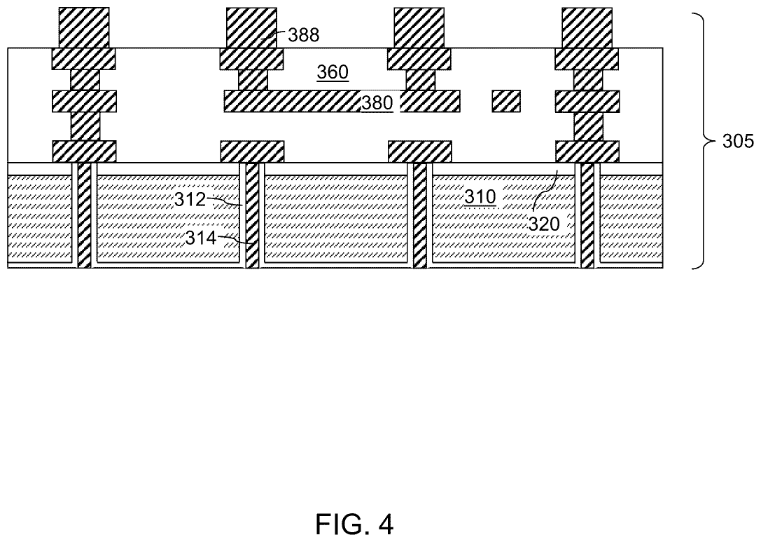

FIG. 3 is vertical cross-sectional view of the intermediate structure after attachment of local silicon interconnect bridges 305 according to an embodiment of the present disclosure. FIG. 4 is a schematic vertical cross-sectional view of a local silicon interconnect bridge 305. Referring to FIGS. 3 and 4, a plurality of local silicon interconnect (LSI) bridges 305 may be attached to the first carrier wafer 810. Each LSI bridge 305 includes a silicon substrate 310 (as thinned and diced during manufacturing of the local silicon interconnect bridge 305), through-silicon via structures 314 vertically extending through the silicon substrate 310, through-substrate openings that vertically extend through the silicon substrate 310, a dielectric liner 312 that provides electrical isolation for the through-silicon via structures 314, backside dielectric material layer 320, and metal interconnect structures 380 embedded in dielectric material layers 360 and electrically connected to the through-silicon via structures 314 and/or electrically connected to one another. Metal pads, which are herein referred to as LSI metal pads 388, may be provided on the topmost metal interconnect structures 380.

The LSI bridges 305 may be placed within openings in the arrays of the TIV structures 386 on the top surface of the first adhesive layer 811. Generally, a pick and place tool may be used to place at least one LSI bridge 305 within each unit area UA. At least one local silicon interconnect (LSI) bridge 305 may be placed within each unit area UA of repetition using the pick and place tool. In one embodiment, a plurality of LSI bridges 305 may be placed within each unit area UA of repetition using the pick and place tool.

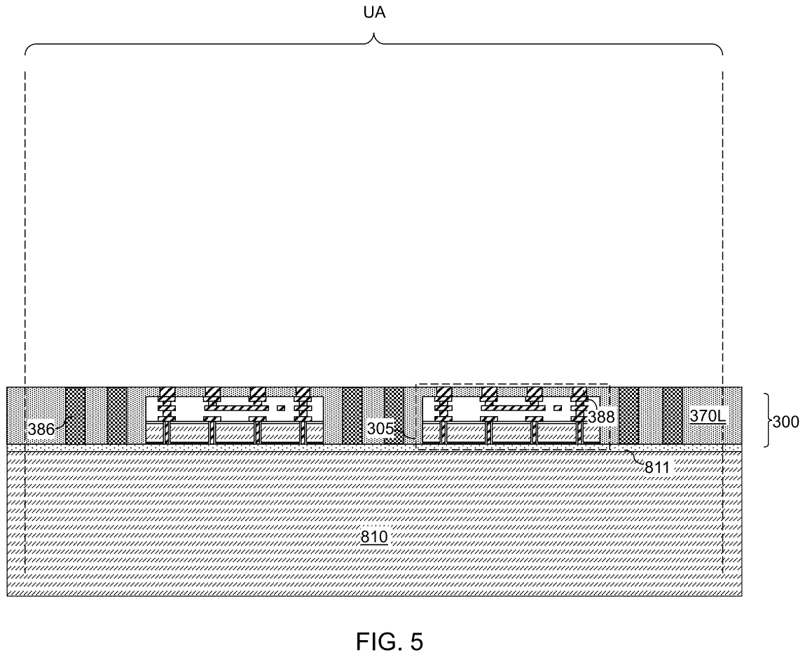

Referring to FIG. 5, an encapsulant, such as a molding compound (MC) may be applied to the gaps within the assembly of the LSI bridges 305 and the TIV structures 386. The MC includes an epoxy-containing compound that may be hardened (i.e., cured) to provide a dielectric material portion having sufficient stiffness and mechanical strength. The MC may include epoxy resin, hardener, silica (as a filler material), and other additives. The MC may be provided in a liquid form or in a solid form depending on the viscosity and flowability. Liquid MC typically provides better handling, good flowability, less voids, better fill, and less flow marks. Solid MC typically provides less cure shrinkage, better stand-off, and less die drift. A high filler content (such as 85% in weight) within an MC may shorten the time in mold, lower the mold shrinkage, and reduce the mold warpage. Uniform filler size distribution in the MC may reduce flow marks, and may enhance flowability.

The MC may be cured at a curing temperature to form an MC matrix, which is herein referred to as a first molding compound matrix 370L or an interposer-level molding compound (MC) matrix. The first molding compound matrix 370L laterally encloses each of the LSI bridges 305 and the TIV structures 386. The first molding compound matrix 370L may be a continuous material layer that extends across the entirety of the area of a reconstituted wafer overlying the first carrier wafer 810.

Subsequently, excess portions of the first molding compound matrix 370L may be removed from above the horizontal plane including the top surfaces of the LSI bridge 305 and the TIV structures 386 by a planarization process, which may use chemical mechanical planarization (CMP). Surfaces of the through-silicon via structures 314 may be physically exposed after the planarization process. The remaining portion of the first molding compound matrix 370L may have a top surface within a horizontal plane including top surfaces of the LSI bridge 305 and the TIV structures 386.

The first molding compound matrix 370L includes a plurality of molding compound (MC) interposer frames located within a respective unit area UA and are laterally adjoined to one another. Each MC interposer frame corresponds to a portion of the first molding compound matrix 370L located within a unit area UA, i.e., an area of a single interposer to be subsequently formed. Each MC interposer frame laterally surrounds a respective set of at least one LSI bridge 305 and a respective array of TIV structures 386. A bridge-level interposer layer 300 may be formed.

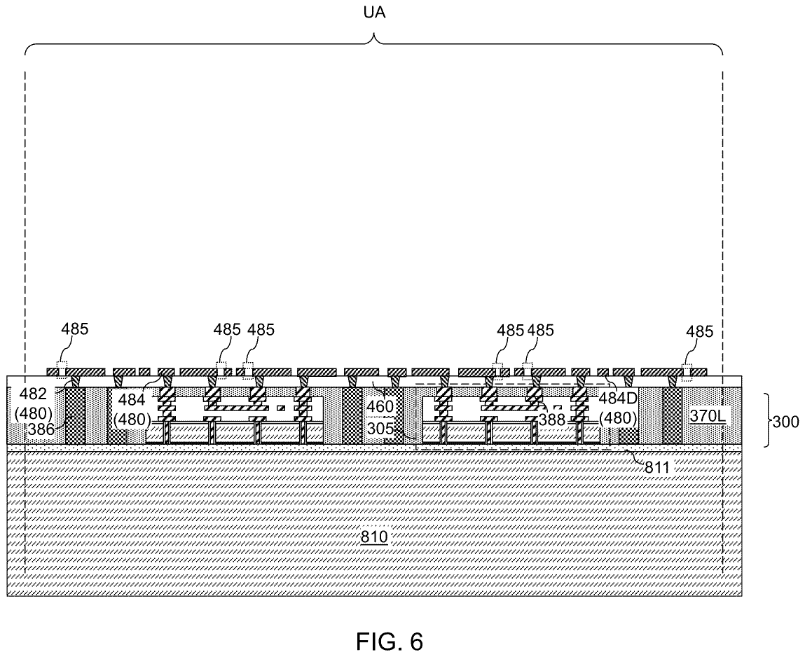

Subsequently, first redistribution wiring interconnects 480 formed within first redistribution dielectric layers 460 may be formed. FIG. 6 is a vertical cross-sectional view of the intermediate structure after formation of a first subset of first redistribution wiring interconnects 480 and a first subset of first redistribution dielectric layers 460. The total number of metal line levels of the first redistribution wiring interconnects 480 may be in a range from 1 to 10, such as from 1 to 4. While the present disclosure is described using an embodiment in which the total number of metal line levels is 1, embodiments are expressly contemplated herein in which 2 or more levels of metal lines are used for the first redistribution wiring interconnects 480.

The first redistribution dielectric layers 460 include a respective dielectric polymer material such as polyimide (PI), benzocyclobutene (BCB), or polybenzobisoxazole (PBO). Each first redistribution dielectric layer 460 may be formed by spin coating and drying of the respective dielectric polymer material. The thickness of each first redistribution dielectric layer 460 may be in a range from 2 microns to 30 microns, such as from 3 microns to 20 microns. Each first redistribution dielectric layer 460 may be patterned, for example, by applying and patterning a respective photoresist layer thereabove, and by transferring the pattern in the photoresist layer into the first redistribution dielectric layer 460 using an etch process such as an anisotropic etch process. The photoresist layer may be subsequently removed, for example, by ashing.

Each of the first redistribution wiring interconnects 480 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 40 nm to 800 nm, and the copper seed layer may have a thickness in a range from 100 nm to 400 nm. The metallic fill material for the first redistribution wiring interconnects 480 may include copper, nickel, or copper and nickel. The thickness of the metallic fill material that is deposited for each first redistribution wiring interconnect 480 may be in a range from 2 microns to 30 microns, such as from 3 microns to 10 microns, although lesser or greater thicknesses may also be used.

The first subset of the first redistribution wiring interconnects 480 may comprise all of the first redistribution wiring interconnects 480 except topmost first redistribution wiring interconnects 480. In one embodiment, the first subset of the first redistribution wiring interconnects 480 may comprise metal via structures 482, metal line structures 484, and dummy metal line structures 484D. The metal via structures 482 provide vertically-extending electrically conductive paths, the metal line structures 484 provide horizontally-extending electrically conductive paths, and the dummy metal line structures 484D are electrically floating and thus, do not provide any electrically conductive path.

According to an aspect of the present disclosure, the first subset of the first redistribution wiring interconnects 480 may comprise elements for increasing mechanical stability and adhesion. For example, the dummy metal line structures 484D may be positioned in a manner that increases the contact area between the first redistribution wiring interconnects 480 and the redistribution dielectric layers 460. Further, the metal line structures 484 may have layouts that enhance adhesion between the first redistribution wiring interconnects 480 and the redistribution dielectric layers 460. In one embodiment, a subset of the first redistribution wiring interconnects 480 may be formed with at least one element for enhancing adhesion. For example, the at least one element may include one or more of the following elements: a first element comprising multiple interconnected metal line segments such that adjoined pairs of line segments have different horizontal propagation directions that differ by a respective acute angle; a second element comprising a one-dimensional array of straight metal lines having a uniform width that is less than a width of each of the die-side bump structures 488 and having a uniform spacing that is less than the width of each of the die-side bump structures 488 (i.e., first bump structures 488); and a third element comprising a two-dimensional array of metal pads each having a width that is not greater than 250 % of a width of each of the die-side bump structures 488 and each having a length that is not greater than 250 % of the width of each of the die-side bump structures 488.

In one embodiment, a subset of the first redistribution wiring interconnects 480 may comprise vertically-extending through holes 485. For example, a subset of the metal line structures 484 may have a respective through hole 485 therethrough. The through holes 485 may contain a void (i.e., a volume that is not filled with any solid phase material or any liquid phase material), or may be filled with a respective portion of a first redistribution dielectric layer 460.

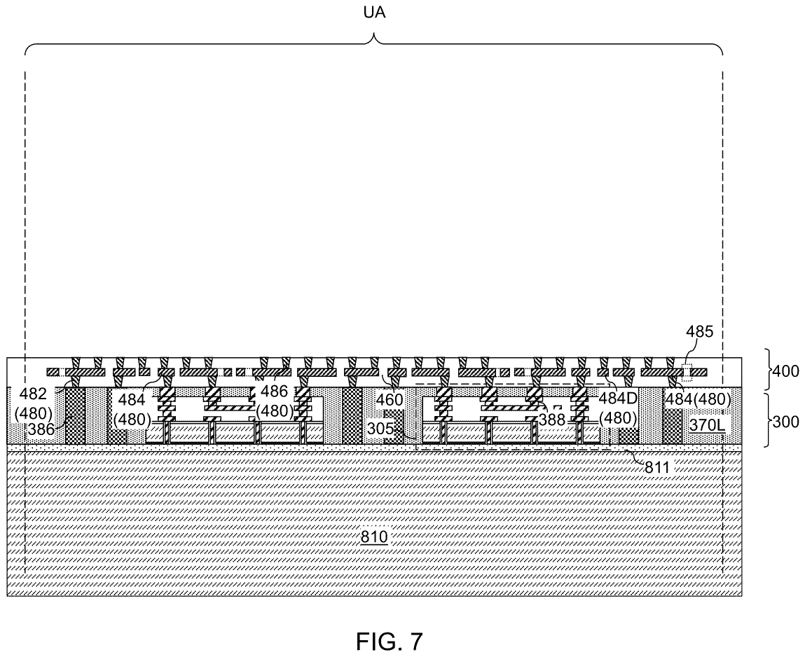

Referring to FIG. 7, a second subset of the first redistribution wiring interconnects 480 and a topmost first redistribution dielectric layer 460 may be formed. The second subset of the first redistribution wiring interconnects 480 comprises topmost first redistribution wiring interconnects 480. In one embodiment, the topmost first redistribution wiring interconnects 480 may comprise metal via structures that are most proximal to semiconductor dies upon subsequently bonding the semiconductor dies to interposers. As such, the topmost first redistribution wiring interconnects 480 are herein referred to as proximal metal via structures 486. A first subset of the proximal metal via structures 486 may be formed on a respective one of the metal line structures 484, and a second subset of the proximal metal via structures 486 may be formed on a respective one of the dummy metal line structures 484D. The top surfaces of the proximal metal via structures 486 may be coplanar with the topmost surface of the first redistribution dielectric layers 460.

In one embodiment, a subset of the first redistribution wiring interconnects 480 comprises a respective vertically-extending through hole 485 therein. In this embodiment, the respective vertically-extending through hole 485 may be filled with a dielectric material of one of the first redistribution dielectric layers 460 (such as a topmost first redistribution dielectric layer 460). A first redistribution structure 400 may be formed within each unit area UA. Each first redistribution structure 400 comprises first redistribution wiring interconnects 480 embedded within first redistribution dielectric layers 460. Each combination of a die-level interposer layer 300 and a first redistribution structure 400 within a unit area UA constitutes an interposer (300, 400). A reconstituted wafer including a two-dimensional array of interposers (300, 400) may be formed over the first carrier wafer 810.

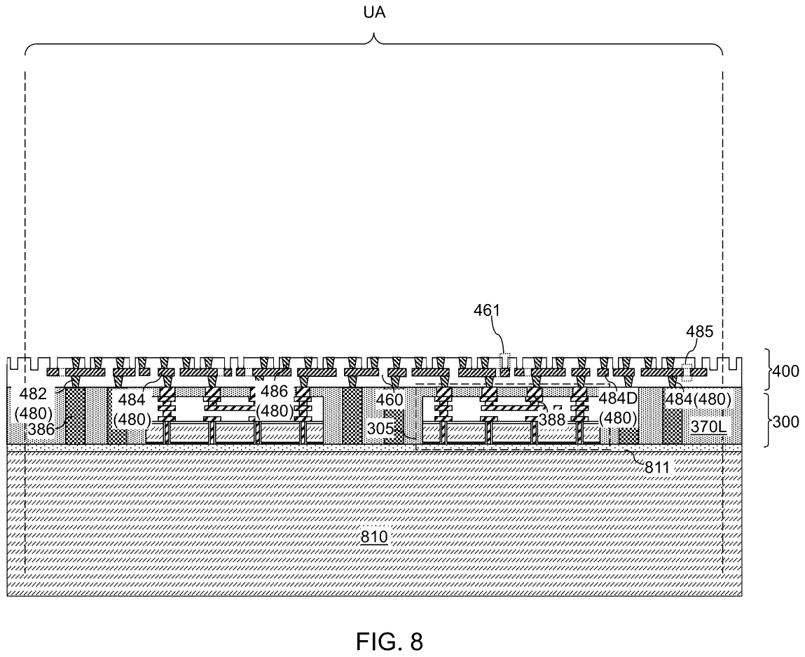

Referring to FIG. 8, topographical elements may be formed which enhance adhesion between the first redistribution dielectric layers 460 and moisture-resistant materials to be subsequently formed. For example, a photoresist layer (not shown) may be applied over the first redistribution dielectric layers 460, and may be lithographically patterned in areas that overlie segments of the metal line structures 484 and the dummy metal line structures 484D. An anisotropic etch process may be performed to form openings 461 through the topmost first redistribution dielectric layer 460. The openings 461 vertically extend downward from the topmost surface of the first redistribution dielectric layers 460 such that top surface segments of a subset of the first redistribution wiring interconnects 480 are physically exposed underneath the openings 461. Surface segments of top surfaces of the metal line structures 484 and the dummy metal line structures 484D may be physically exposed underneath the openings 461 through the topmost first redistribution dielectric layer 460. The photoresist layer may be subsequently removed, for example, by ashing. A degassing process, such as an anneal in a moisture-free environment, may be performed to outgass moisture from the first redistribution dielectric layers 460. In this embodiment, the openings 461 in the topmost first redistribution dielectric layer 460 and the through holes 485 in the metal line structures 484 may be used as outgassing paths during the degassing process.

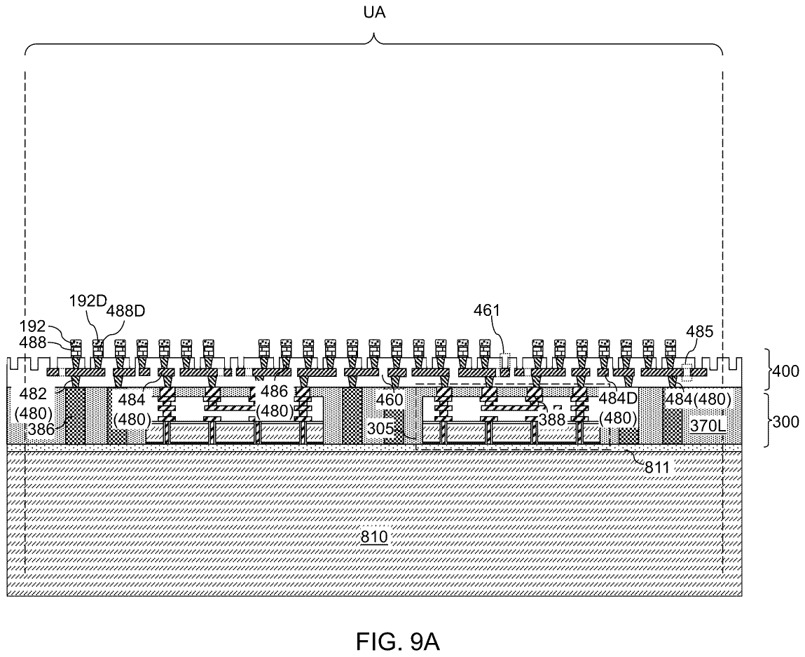

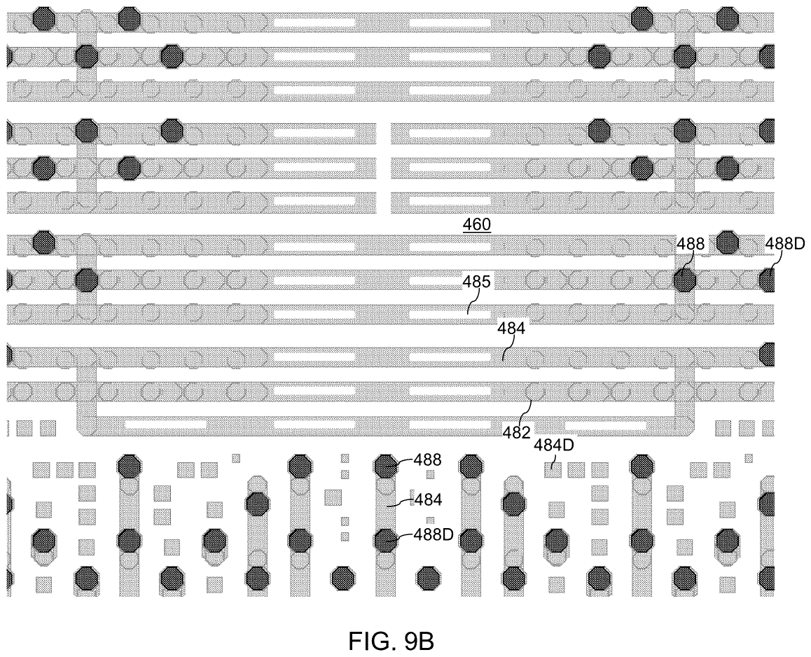

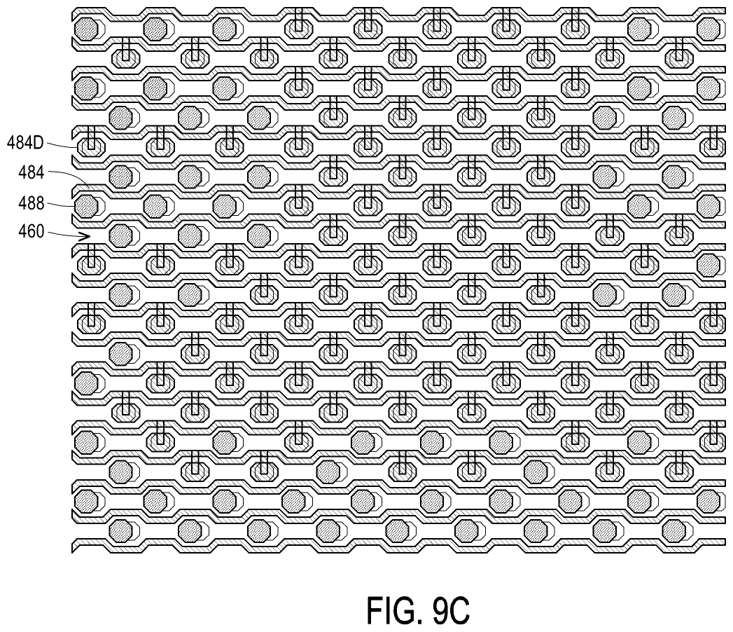

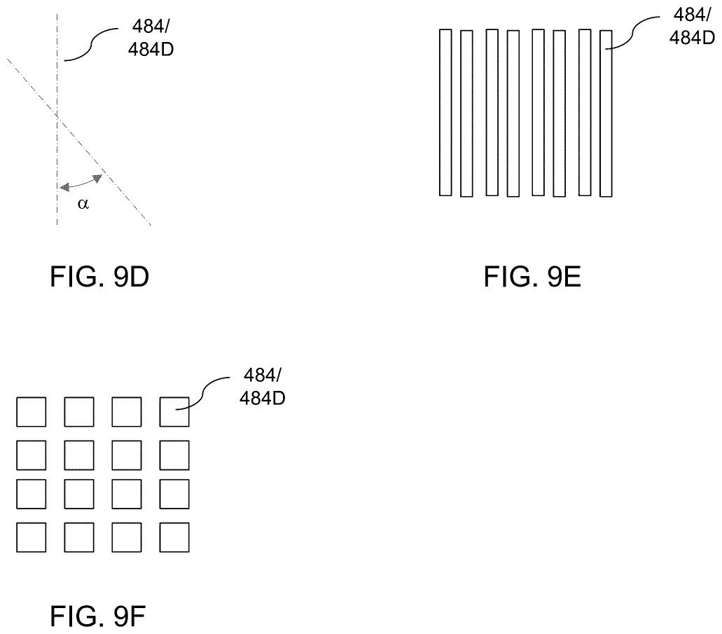

FIG. 9A is a vertical cross-sectional view of the intermediate structure after formation of die-side bump structures 488, dummy bump structures 488D, solder material portions 192, and dummy solder material portions 192D according to an embodiment of the present disclosure. FIG. 9B is a first exemplary layout for the second subset of the first redistribution wiring interconnects 480, the die-side bump structures 488, and the dummy bump structures 488D according to an embodiment of the present disclosure. FIG. 9C is a second exemplary layout for the second subset of the first redistribution wiring interconnects 480, the die-side bump structures 488, and the dummy bump structures 488D according to an embodiment of the present disclosure. FIGS. 9D, 9E, and 9F illustrate elements that may be used for the second subset of the first redistribution wiring interconnects 480 according to an embodiment of the present disclosure.

Referring to FIGS. 9A-9F , the die-side bump structures 488 and the dummy bump structures 488D may be formed on the topmost subset of the first redistribution wiring interconnects 480 such as the proximal metal via structures 486. In an illustrative example, an under bump metallization (UBM) layer (not shown) may be deposited over the proximal metal via structures 486 and the first redistribution dielectric layers 460. The UBM layer may comprise a layer stack including at least one adhesion layer and a metallic seed layer that functions as a template for initiating a subsequent electroplating process. In embodiments in which openings 461 are present in the topmost first redistribution dielectric layer 460, the UBM layer may be deposited in peripheral regions of the openings 461. For example, the UBM layer may comprise a layer stack that includes, from bottom to top, a titanium layer, a titanium nitride layer, a copper seed layer, and a nickel layer. The nickel layer may provide the functionality of serving as a barrier to prevent copper diffusion into the solder material, thereby enhancing the long-term reliability of the bump structure.

A photoresist layer (not shown) may be deposited over the UBM layer and may be lithographically patterned to form openings over the areas of the proximal metal via structures 486. In one embodiment, an opening through the photoresist layer may be formed over each of the proximal metal via structures 486. An electroplating process may be subsequently performed to deposit an electroplatable material (such as copper) within the openings in the photoresist layer. Copper pillar structures are electroplated within the openings in the photoresist layer. The lateral dimensions of each copper pillar structure may be in a range from 5 micron to 50 microns. The height of each copper pillar structure may be in a range from 10 microns to 40 microns. In one embodiment, the copper pillar structures may be formed as microbump structures. The photoresist layer may be subsequently removed, for example, by ashing. Unmasked portions of the UBM layer (which are not covered by the copper pillar structures) may be subsequently removed by performing an etch process, which may comprise an isotropic etch process such as a wet etch process. Remaining contiguous combination of a respective patterned portion of the UBM layer and a respective copper pillar structure comprise die-side bump structures 488 (i.e., bump structures that face semiconductor dies for bonding) and dummy bump structures 488D.

The die-side bump structures 488 and the dummy bump structures 488D are formed on a respective one of the first redistribution wiring interconnects 480, such as a respective one of the proximal metal via structures 486. If openings 461 vertically extend through a topmost first redistribution dielectric layer 460, top surface segments of a subset of the first redistribution wiring interconnects 480 are exposed after formation of the die-side bump structures 488 underneath the openings 461 in the topmost first redistribution dielectric layer 460.

The die-side bump structures 488 and the dummy bump structures 488D may be formed using a same set of material deposition processes and patterning processes, and as such, may have the same material composition and the same vertical extent. The difference between the die-side bump structures 488 and the dummy bump structures 488D is that the die-side bump structures 488 are subsequently used as bonding structures for attaching semiconductor dies, while the dummy bump structures 488D are not used as bonding structures. Thus, the dummy bump structures 488D are not subsequently used to provide electrically conductive paths to any semiconductor die. In one embodiment, the die-side bump structures 488 may be formed as periodic arrays, and the dummy bump structures 488D may be positioned between a respective neighboring pair of die-side bump structures 488.

According to an aspect of the present disclosure, a first subset of the dummy bump structures 488D may be formed such that each dummy bump structure 488D within the first subset of the dummy bump structures 488D is electrically connected to a respective die-side bump structure 488 selected from the die-side bump structures 488 of each interposer (300, 400). For example, each dummy bump structure 488D within the first subset of the dummy bump structures 488D may be formed on a respective proximal metal via structure 486 which contacts a respective metal line structure 484 contacting a bottom surface of another proximal metal via structure 486 that contacts a bottom surface of a die-side bump structure 488. In one embodiment, a second subset of the dummy bump structures 488D may be formed such that each dummy bump structure 488D within the second subset of the dummy bump structures 488D is electrically disconnected from each of the die-side bump structures 488. For example, each dummy bump structure 488D within the second subset of the dummy bump structures 488D may be formed on a respective proximal metal via structure 486 which contacts a respective dummy metal line structure 484D that does not contact any other first redistribution wiring interconnect 480 except the respective proximal metal via structure 486.

Subsequently, solder material portions 192 and dummy solder material portions 192D may be formed. Specifically, the solder material portions 192 may be attached to the die-side bump structures 488, and dummy solder material portions 192D may be attached to the dummy bump structures 488D. In one embodiment, the solder material portions 192 and the dummy solder material portions 192D may be deposited by screen printing solder paste onto the die-side bump structures 488 and the dummy bump structures 488D. Alternatively, the solder material portions 192 and the dummy solder material portions 192D may be disposed on the die-side bump structures 488 and the dummy bump structures 488D by placing pre-formed solder balls on top of the die-side bump structures 488 and the dummy bump structures 488D. The solder material portions 192 and the dummy solder material portions 192D may comprise a lead-free alloy such as a tin-silver-copper alloy.

A reflow process may be performed to heat the intermediate structure including the first carrier wafer 810, the bridge-level interposer layer 300, and the first redistribution structures 400 to a reflow temperature. Upon reflow of the solder material, the solder material portions 192 are attached to the die-side bump structures 488, and dummy solder material portions 192D are attached to the dummy bump structures 488D.

In one embodiment, a subset of the first redistribution wiring interconnects 480 may be formed with at least one element which is selected from: a first element comprising multiple interconnected metal line segments such that adjoined pairs of line segments have different horizontal propagation directions that differ by a respective acute angle a (as illustrated in FIG. 9D); a second element comprising a one-dimensional array of straight metal lines having a uniform width that is less than a width of each of the die-side bump structures 488 and having a uniform spacing that is less than the width of each of the die-side bump structures 488 (as illustrated in FIG. 9E); and a third element comprising a two-dimensional array of metal pads each having a width that is not greater than 250% of a width of each of the die-side bump structures 488 and each having a length that is not greater than 250% of the width of each of the die-side bump structures 488 (as illustrated in FIG. 9F). In one embodiment, the width of each of the die-side bump structures 488 may be in a range from 5 microns to 50 microns, such as from 10 microns to 40 microns (e.g., 20 microns), although lesser and greater widths may also be used.

FIGS. 9B and 9C illustrate layouts for the metal line structures 484, the die-side bump structures 488, and the dummy bump structures 488D. Vertically-extending through holes 485 in the metal line structures 484 are illustrated in FIG. 9B. The metal line structures 484 illustrated in FIG. 9C include the elements described with reference to FIG. 9D and FIG. 9E.

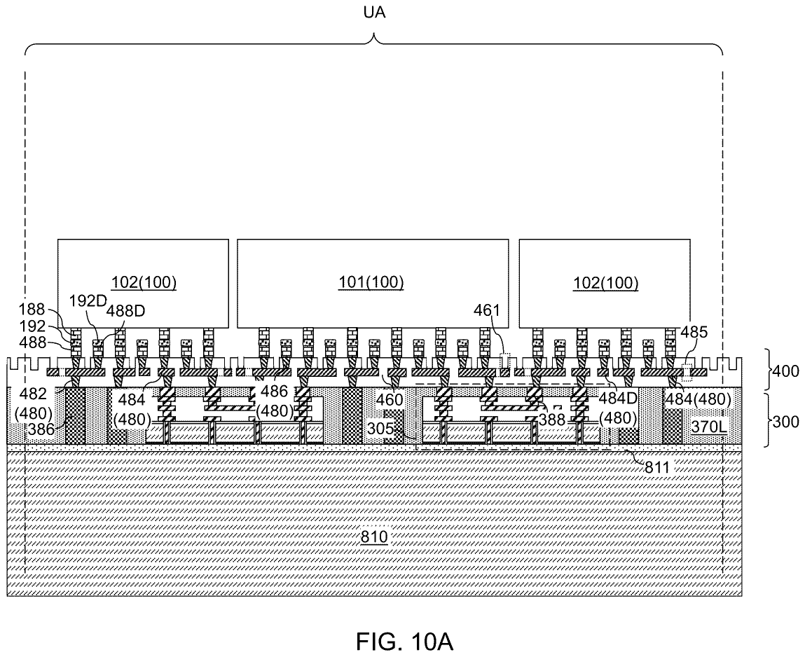

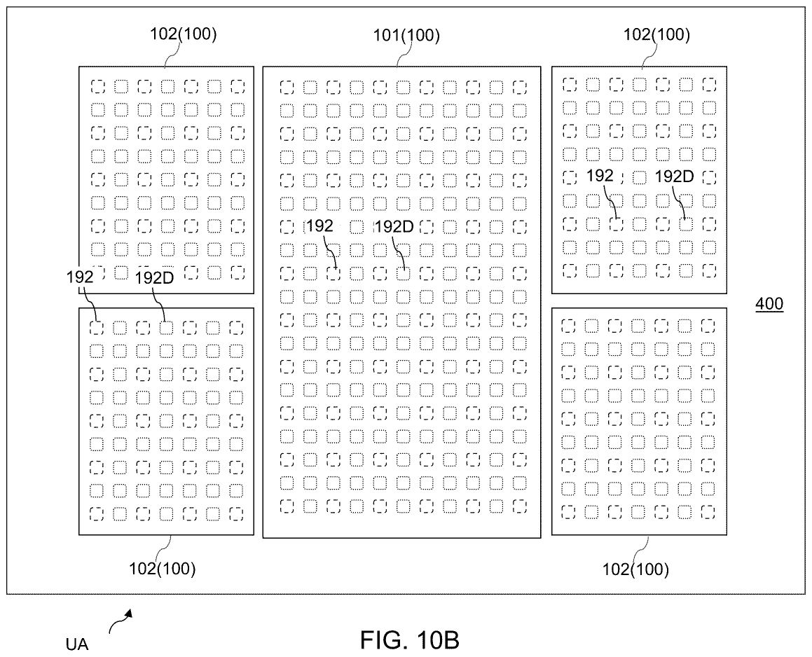

Referring to FIGS. 10A and 10B, a set of at least one semiconductor die 100 may be bonded to a respective set of die-side bump structures 488 within each unit area UA. Each set of at least one semiconductor die 100 includes at least one semiconductor die 100, and may comprise a plurality of semiconductor dies 100. In one embodiment, each set of at least one semiconductor die 100 may include at least one processor die 101 and/or at least one memory die 102. Each processor die 101 may comprise at least one central processor unit (CPU), at least one graphic processor unit (GPU), at least one neural processor unit (NPU), and/or at least one digital signal processor (DSP). In one embodiment, the at least one processor die 101 may comprise a system-on-chip (SoC) die such as an application processor die. In one embodiment, the at least one memory die 102 may comprise a high bandwidth memory (HBM) die that includes a vertical stack of static random access memory dies. Each HBM die may comprise a vertical stack of static random access memory (SRAM) dies that are interconnected to one another through arrays of microbumps and are laterally surrounded by a respective molding material enclosure frame.

Each semiconductor die 100 may comprise a respective array of on-die bump structures 188 (i.e., second bump structures 188). Each of the semiconductor dies 100 may be positioned in a face-down position such that on-die bump structures 188 face the solder material portions 192. Placement of the semiconductor dies 100 may be performed using a pick and place apparatus such that each of the on-die bump structures 188 may face a respective one of the solder material portions 192. Each set of at least one semiconductor die 100 may be placed within a respective unit area.

In one embodiment, the on-die bump structures 188 and the die-side bump structures 488 may be configured for microbump bonding. In this embodiment, each of the on-die bump structures 188 and the die-side bump structures 488 may be configured as copper pillar structures having a diameter in a range from 10 microns to 50 microns, and may have a respective height in a range from 10 microns to 40 microns. The pitch of the microbumps in the direction of periodicity may be in a range from 20 microns to 100 microns, although lesser and greater pitches may also be used. Upon reflow, the solder material portions 192 provide solder-mediated bonding between vertically-neighboring pairs of an on-die bump structures 188 and a die-side bump structure 488.

Generally, at least one semiconductor die 100 comprising a respective array of on-die bump structures 188 may be attached to a respective subset of the die-side bump structures 488 of the interposer (300, 400) in each unit area UA. In one embodiment, the at least one semiconductor die 100 is attached to the interposer (300, 400) using at least one array of solder material portions 192. According to an embodiment, the dummy bump structures 488D are not bonded to any of the at least one semiconductor die 100. In one embodiment, each of the at least one semiconductor die 100 comprises a respective array of on-die bump structures 188 that is bonded to a respective subset of the die-side bump structures 488 of the interposer (300, 400) while attaching the at least one semiconductor die 100 to the interposer (300, 400).

Within each unit area UA, an assembly of an interposer (300, 400) and at least one semiconductor die 100 may be formed. The interposer (300, 400) comprises first redistribution wiring interconnects 480 embedded within first redistribution dielectric layers 460, and die-side bump structures 488 and dummy bump structures 488D contacting a respective one of the first redistribution wiring interconnects 480. Each of the at least one semiconductor die 100 comprises a respective array of on-die bump structures 188 that is bonded to a respective subset of the die-side bump structures 488 through a respective array of solder material portions 192. The dummy bump structures 488D are not bonded to any of the at least one semiconductor die 100. Generally, the dummy bump structures 488D do not contact any of the at least one semiconductor die 100 due to absence of any overlying on-die bump structure 188. Thus, a vertical gap is present between each dummy bump structure 488D and the at least one semiconductor die 100. The height of each vertical gap may be on the order of the thickness of an on-die bump structure 188.

In one embodiment, each of the dummy bump structures 488D may be contacted by a respective dummy solder material portion 192D. In one embodiment, the dummy solder material portions 192D are not in direct contact with any of the at least one semiconductor die 100. Thus, a gap is present between each dummy solder material portion 192D and a bottom surface of an overlying semiconductor die 100. In one embodiment, the entirety of the dummy bump structures 488D have an areal overlap with the at least one semiconductor die 100 in a plan view within each unit area UA (as illustrated in FIG. 10B). In one embodiment, a top surface of the first redistribution dielectric layers 460 comprises indentations (i.e., openings 461) that comprise openings 461 that vertically extend through a topmost redistribution dielectric layer 460 selected from the first redistribution dielectric layers 460.

Generally, the dummy bump structures 488D are not bonded to any of the at least one semiconductor die 100 after the at least one semiconductor die 100 is attached to the interposer (300, 400). The on-die bump structures 188 are bonded to the die-side bump structures 488 through the solder material portions 192. The dummy bump structures 488D do not contact the at least one semiconductor die 100 after the at least one semiconductor die 100 is bonded to the interposer (300, 400) in each unit area UA.

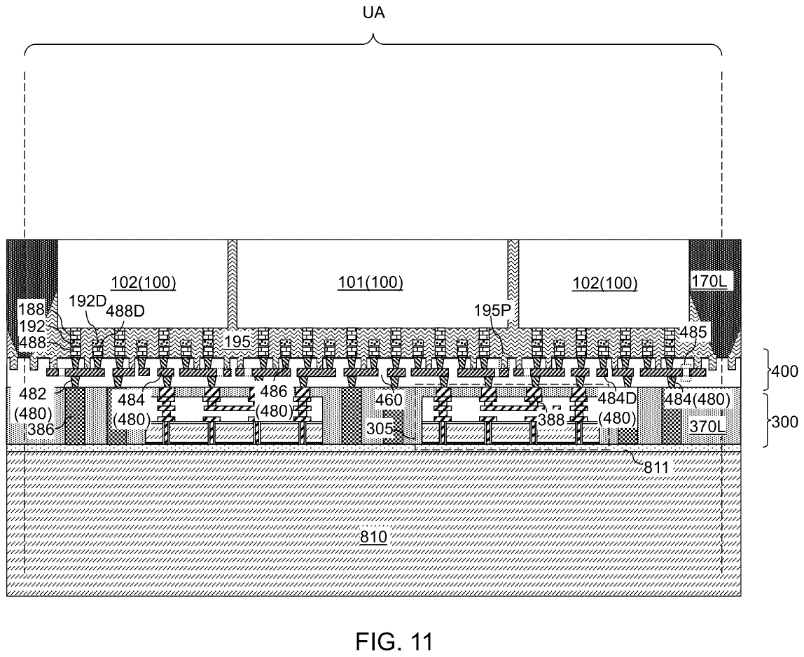

Referring to FIG. 11, a first underfill material (also referred to as a dielectric layer) may be applied into each gap between the interposers (300, 400) and a respective set of at least one semiconductor die 100. The first underfill material may comprise any underfill material known in the art. The first underfill material may be applied between the interposer (300, 400) and the semiconductor die 100 around the solder material portions 192 and the dummy solder material portions 192D within each unit area UA. An underfill material portion 195 may be formed by injecting the material around the solder material portions 192 and the dummy solder material portions 192D. Any known underfill material application method may be used, such as the capillary underfill method, the molded underfill method, or the printed underfill method.

Thus, an underfill material portion 195 may be formed within each unit area UA between the interposer (300, 400) and the respective set of at least one semiconductor die 100. At least one semiconductor die 100 comprising a respective set of on-die bump structures 188 is attached to the interposer (300, 400) through a respective set of solder material portions 192. The underfill material portion 195 may laterally surround and contact all solder material portions 192 and dummy solder material portions 192D within a unit area UA. The underfill material portion 195 may contact the solder material portions 192, the die-side bump structures 488, the dummy bump structures 488D, and the on-die bump structures 188. In one embodiment, all surfaces of the dummy solder material portions 192D may be contacted by a combination of the underfill material portion 195 and the dummy bump structures 488D.

In one embodiment, the underfill material portion 195 fills the openings 461 that extend downward from the topmost surface of the first redistribution dielectric layers 460. In this embodiment, the underfill material portion 195 may comprise downward protrusions 195P that fill the indentations in the top surface of the first redistribution dielectric layers 460 (i.e., the openings 461 through the topmost first redistribution dielectric layer 460). Each solder material portion 192 and each dummy solder material portion 192D are laterally surrounded by, and are contacted by, the underfill material portion 195 in each unit area UA.

A second molding compound (MC) may be applied to the gaps between assemblies of a respective set of semiconductor dies 100 and a respective underfill material portion 195. The second MC may include any material that may be used for the first molding compound matrix 370L discussed above. The second MC may include epoxy resin, hardener, silica (as a filler material), and other additives. The second MC may be cured at a curing temperature to form a molding compound matrix, which is herein referred to as a die-level molding compound matrix or as a second molding compound matrix 170L. The second molding compound matrix 170L laterally surrounds and embeds each assembly of a set of semiconductor dies 100 and an underfill material portion 195. The second molding compound matrix 170L includes a plurality of molding compound (MC) die frames that are laterally adjoined to one another. Each MC die frame is a portion of the second molding compound matrix 170L that is located within a respective unit area UA. Thus, each MC die frame laterally surrounds, and embeds, a respective a set of semiconductor dies 100 and a respective underfill material portion 195. Young's modulus of pure epoxy is about 8.35 GPa, and Young's modulus of the MC may be higher than Young's modulus of pure epoxy due to additives therein. Thus, Young's modulus of the second molding compound matrix 170L may be greater than 8.5 GPa.

Portions of the second molding compound matrix 170L that overlies the horizontal plane including the top surfaces of the semiconductor dies 100 may be removed by a planarization process. For example, the portions of the second molding compound matrix 170L that overlies the horizontal plane may be removed using a chemical mechanical planarization (CMP). The reconstituted wafer that overlies the first carrier wafer 810 comprises a combination of the second molding compound matrix 170L, the semiconductor dies 100, the underfill material portions 195, and a two-dimensional array of interposers (300, 400). Each portion of the second molding compound matrix 170L located within a unit area UA constitutes an MC die frame.

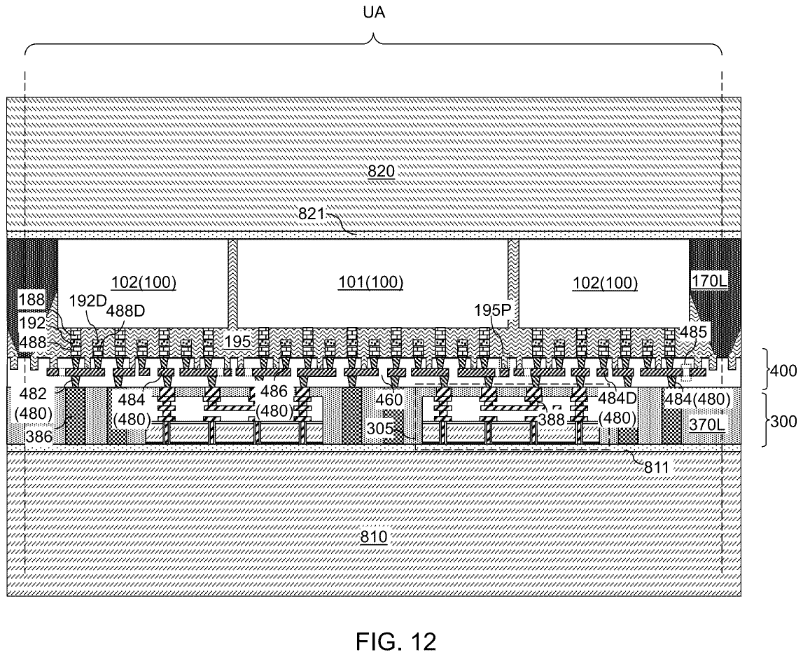

Referring to FIG. 12, a second adhesive layer 821 may be applied over the second molding compound matrix 170L. The second adhesive layer 821 may comprise a light-to-heat conversion (LTHC) layer or a thermally decomposing adhesive material layer depending on the removal mechanism to be subsequently used. A second carrier wafer 820 may be attached to the second molding compound matrix 170L and the semiconductor dies 100 through the second adhesive layer 821. The second carrier wafer 820 may comprise any material that may be used for the first carrier wafer 810, and generally may have about the same thickness range as the first carrier wafer 810.

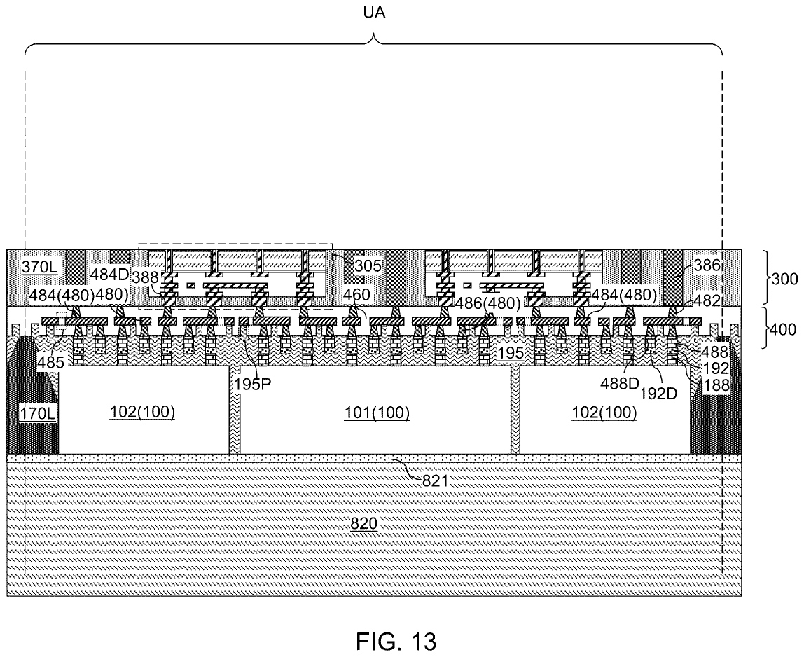

Referring to FIG. 13, the first carrier wafer 810 may be detached from the reconstituted wafer. In some embodiments, the first carrier wafer 810 and the first adhesive layer 811 may be removed by backside grinding. Optionally, at least one selective etch process (such as a wet etch process or a reactive ion etch process) may be used in conjunction with the backside grinding process to minimize collateral removal of surface portions of the LSI bridges 305, and the TIV structures 386. Alternatively or additionally, in embodiments in which the first carrier wafer 810 includes an optically transparent material and the first adhesive layer 811 comprises a light-to-heat conversion material, irradiation through the first carrier wafer 810 may be used to detach the first carrier wafer 810. In embodiments in which the first adhesive layer 811 comprises a thermally decomposable adhesive material, an anneal process or a laser irradiation may be used to detach the first carrier wafer 810. A suitable clean process may be performed to remove residual portions of the first adhesive layer 811.

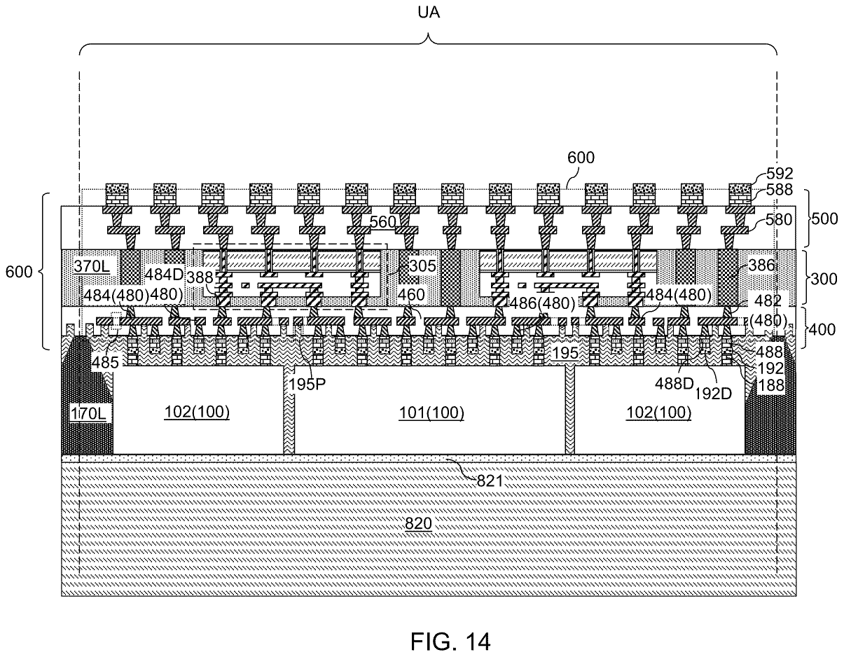

Referring to FIG. 14, a second redistribution structure 500 may be formed on a physically exposed side of the two-dimensional repetition of interposers (300, 400) within each unit area UA. The second redistribution structure 500 comprises second redistribution wiring interconnects 580, second redistribution dielectric layers 560, and substrate-side bonding structures 588. Generally, the second redistribution structure 500 may be formed in the same manner as the first redistribution structures 400 with suitable changes in the lithographic pattern and/or in the thicknesses and material compositions of material layers. The substrate-side bonding structures 588 may be formed as bonding pads that are configured for controlled collapse chip connection (C4) bonding. Solder material portions 592, which are also referred to as substrate-side solder material portions, may be attached to the substrate-side bonding structures 588. If the substrate-side bonding structures 588 are formed as C4 bonding pads, the solder material portions 592 may be formed as C4 solder balls. The second redistribution structure 500 within each unit area UA is incorporated into the interposer (300, 400) within the respective unit area UA to provide a composite interposer 600. Each composite interposer 600 comprises a bridge-level interposer layer 300, a first redistribution structure 400, and a second redistribution structure 500.

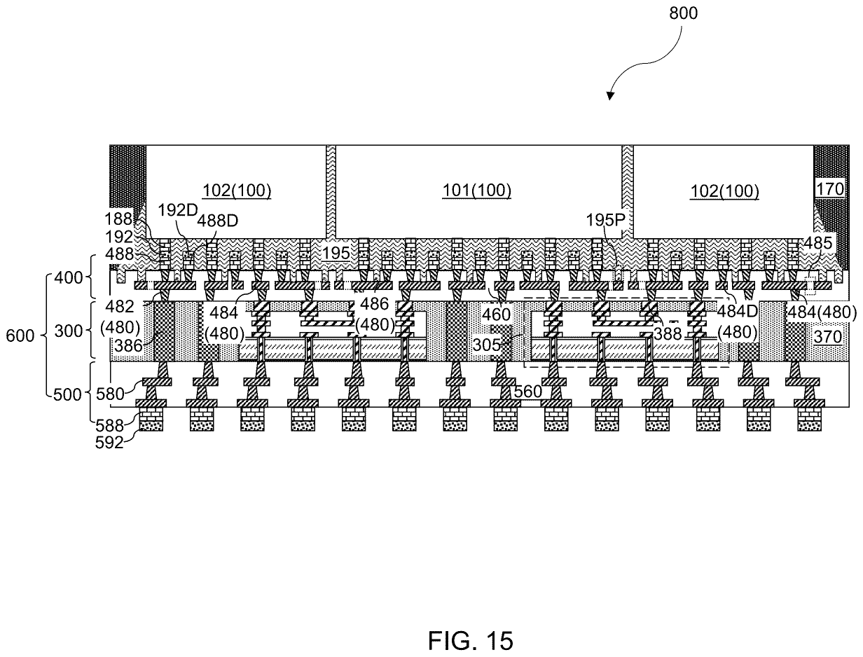

Referring to FIG. 15, the second carrier wafer 820 may be detached from the reconstituted wafer. In embodiments in which the second carrier wafer 820 includes an optically transparent material and the second adhesive layer 821 comprises a light-to-heat conversion material, irradiation through the second carrier wafer 820 may be used to detach the second carrier wafer 820. In embodiments in which the second adhesive layer 821 comprises a thermally decomposable adhesive material, an anneal process or a laser irradiation may be used to detach the second carrier wafer 820. A suitable clean process may be performed to remove residual portions of the second adhesive layer 821. A horizontal surface of the second molding compound matrix 170L may be physically exposed. A reconstituted wafer that is not attached to any carrier wafer may be obtained.

The reconstituted wafer includes a two-dimensional array of composite interposers 600, and further includes a two-dimensional array of sets of at least one semiconductor die 100 that are bonded to a respective composite interposer 600. The reconstituted wafer may be diced along dicing channels (which correspond to the boundaries between neighboring unit areas UA) by performing a dicing process. The dicing channels correspond to the boundaries between neighboring pairs of unit areas UA. Each diced unit from the reconstituted wafer comprises a composite package 800, which may be a fan-out package providing a fan-out connection configuration. Each diced portion of the second molding compound matrix 170L constitutes a die-level MC frame 170. Each diced portion of the first molding compound matrix 370L constitutes an interposer-level MC frame 370.

The diced portions of the reconstituted wafer comprise composite packages 800. Each composite package 800 comprises at least one semiconductor die 100, a composite interposer 600, an underfill material portion 195, a die-level MC frame 170, and at least one array of solder material portions 192. Each composite interposer 600 comprises a bridge-level interposer layer 300, a first redistribution structure 400, and a second redistribution structure 500.

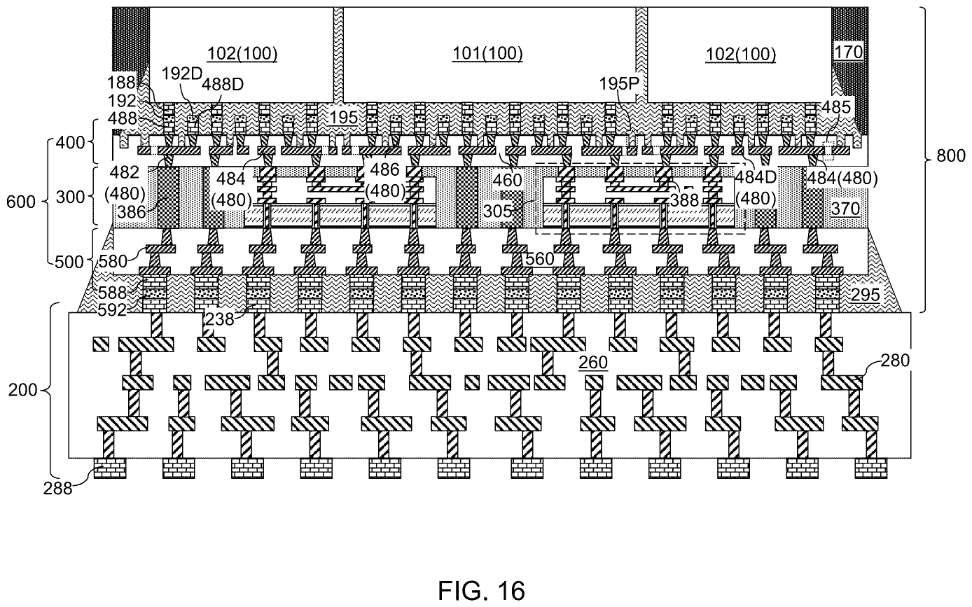

Referring to FIG. 16, a packaging substrate 200 may be provided. The packaging substrate 200 may be a cored packaging substrate including a core substrate, or a coreless packaging substrate that does not include a package core. Alternatively, the packaging substrate 200 may include a system-on-integrated packaging substrate (SoIS) including redistribution layers. dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. It is understood that the scope of the present disclosure is not limited by any particular type of substrate package. For example, an SoIS may be used in lieu of a cored packaging substrate. In embodiments in which SoIS is used, the core substrate may include a glass epoxy plate including an array of through-plate holes.

In one embodiment, the packaging substrate 200 may comprise substrate redistribution dielectric layers 260 having substrate redistribution wiring interconnects 280 formed therein. In one embodiment, the packaging substrate 200 may include board-side surface laminar circuit (SLC) and a chip-side surface laminar circuit (SLC). An array of package-side bonding pads 238 may be provided on the side of the packaging substrate 200 that faces the composite package 800. An array of board-side bonding pads 288 may be formed on the side of the packaging substrate 200 that is subsequently connected to a printed circuit board. The array of board-side bonding pads 288 may be configured to allow bonding through solder joints having a greater dimension than the C4 solder balls.

The composite package 800 may be attached to the packaging substrate 200 using an array of solder balls 592. Specifically, each of the solder balls 592 may be bonded to a respective one of the substrate-side bonding structures 588 and to a respective one of package-side bonding pads 238. A reflow process may be performed to reflow the solder balls 592 during the bonding process.

An underfill material may be applied into a gap between the composite package 800 and the packaging substrate 200. The underfill material may comprise any underfill material known in the art. An underfill material portion may be formed around the array of solder balls 592 in the gap between the composite package 800 and the packaging substrate 200. This underfill material portion is formed between the composite package 800 and the packaging substrate 200, and thus, is herein referred to as an interposer-package underfill material portion 295, or as an IP underfill material portion 295.

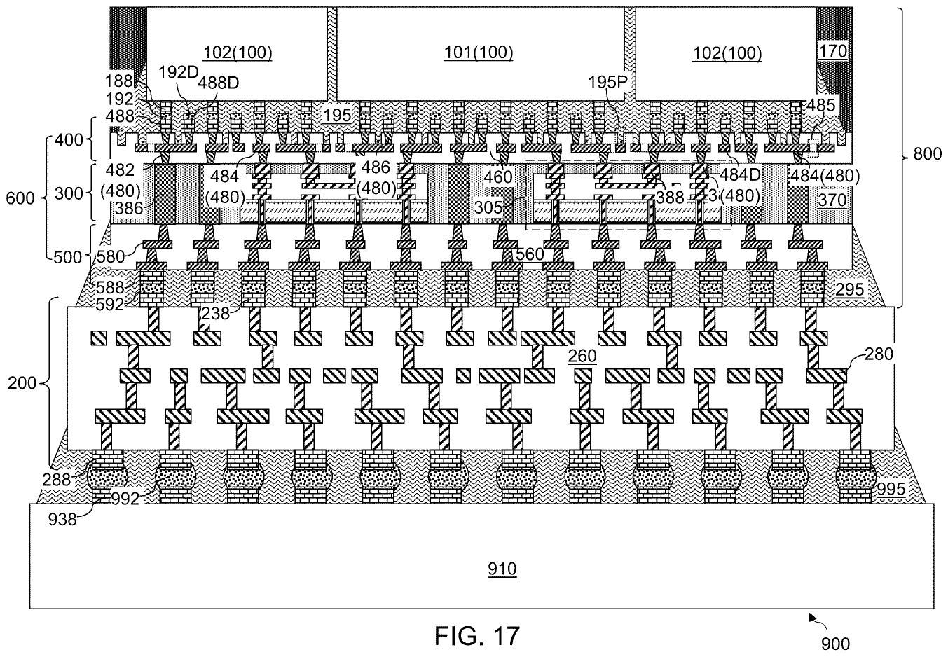

Referring to FIG. 17, a printed circuit board (PCB) 900 including a PCB substrate 910 and PCB bonding pads 938 may be provided. The PCB 900 includes a printed circuitry (not shown) at least on one side of the PCB substrate 910. An array of solder joints 992 may be formed to bond the array of board-side bonding pads 288 to the array of PCB bonding pads 938. The solder joints 992 may be formed by disposing an array of solder balls between the array of board-side bonding pads 288 and the array of PCB bonding pads 938, and by reflowing the array of solder balls. An additional underfill material portion, which is herein referred to as a board-substrate underfill material portion 995 or a BS underfill material portion 995, may be formed around the solder joints 992 by applying and shaping an underfill material. The packaging substrate 200 is attached to the PCB 900 through the array of solder joints 992.

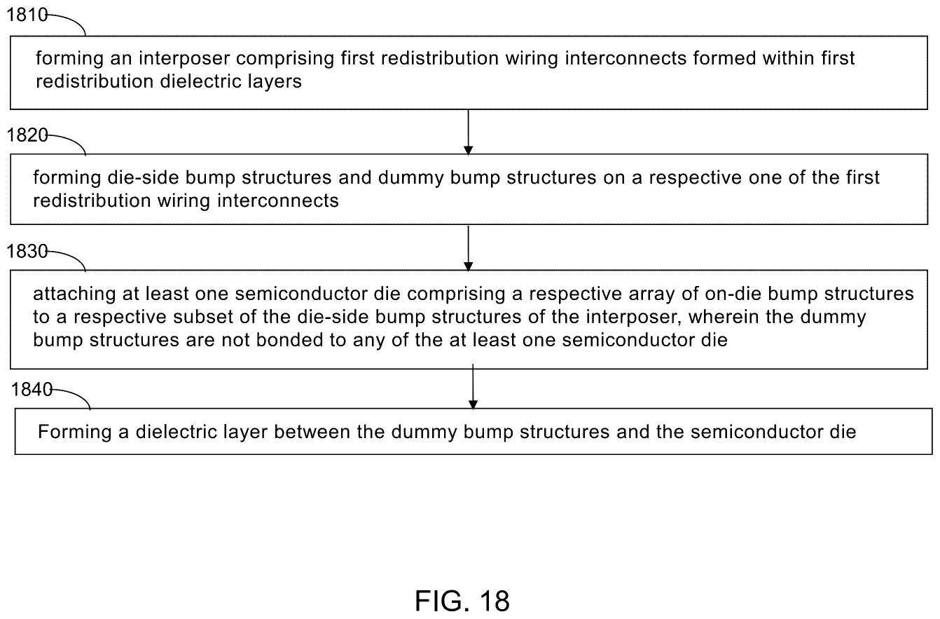

Referring to FIG. 18, a first flowchart illustrates steps for forming a semiconductor structure according to an embodiment of the present disclosure.

Referring to step 1810 and FIGS. 1-8, an interposer (300, 400) comprising first redistribution wiring interconnects 480 formed within first redistribution dielectric layers 460 may be formed.

Referring to step 1820 and FIGS. 9A-9F, first bump structures 488 and dummy bump structures 488D are formed on a respective one of the first redistribution wiring interconnects 480.

Referring to step 1830 and FIGS. 10A-17, at least one semiconductor die 100 comprising a respective array of second bump structures 188 may be attached to a respective subset of the first bump structures 488 of the interposer 600.

Referring to step 1840 and FIGS. 11-17, a dielectric layer 195 (underfill material layer 195) may be formed between the dummy bump structures 488D and the semiconductor die 100. The dummy bump structures 488D are not bonded to any of the at least one semiconductor die 100.

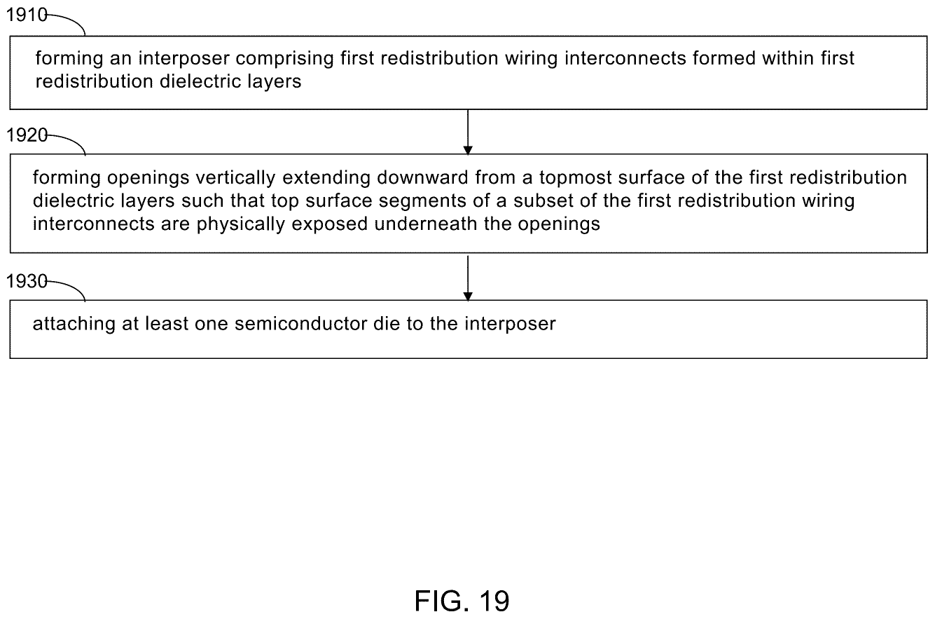

Referring to FIG. 19, a second flowchart illustrates steps for forming a semiconductor structure according to an embodiment of the present disclosure.

Referring to step 1910 and FIGS. 1-7, an interposer 600 comprising first redistribution wiring interconnects 480 formed within first redistribution dielectric layers 460 may be formed.

Referring to step 1920 and FIG. 8, openings 461 vertically extending downward from a topmost surface of the first redistribution dielectric layers 460 may be formed such that top surface segments of a subset of the first redistribution wiring interconnects 480 are physically exposed underneath the openings 461.

Referring to step 1930 and FIGS. 9A-17, at least one semiconductor die 100 may be attached to the interposer 600.

Referring to all drawings and according to various embodiments of the present disclosure, a semiconductor structure comprising an assembly of an interposer 600 and at least one semiconductor die 100 is provided. The interposer 600 comprises first redistribution wiring interconnects 480 formed within first redistribution dielectric layers 460, and first (die-side) bump structures 488 and dummy bump structures 488D contacting a respective one of the first redistribution wiring interconnects 480; each of the at least one semiconductor die 100 comprises a respective array of second bump structures 188 (also referred to as on-die bump structures 188) that is bonded to a respective subset of the first bump structures 488 through a respective array of solder material portions 192; and a dielectric formed between the dummy bump structures 488D and the semiconductor die 100.

In one embodiment, each of the dummy bump structures 488D is contacted by a respective dummy solder material portion 192D. In one embodiment, the dummy solder material portions 192D are not in direct contact with any of the at least one semiconductor die 100. In one embodiment, the dummy bump structures 488D have an areal overlap with the at least one semiconductor die 100 in a plan view. In one embodiment, a top surface of the first redistribution dielectric layers 460 comprises indentations; each array of solder material portions 192 is laterally surrounded by an underfill material portion 195; and the underfill material portion 195 comprises downward protrusions that fill the indentations in the top surface of the first redistribution dielectric layers 460.

Embodiments of the present disclosure provide a semiconductor structure that enhances reliability by addressing moisture-induced delamination in redistribution wiring interconnects 480 and redistribution dielectric layers 460. A combination of first bump structures 488 and dummy bump structures 488D may be used to improve mechanical stability and reduce the effects of moisture absorption. Elements such as through holes 485, fine line structures, and vertically extending openings 461 filled with downward protrusions of underfill material portions 195 may be used to improve adhesion between the redistribution wiring interconnects 480 and the redistribution dielectric layers 460, thereby reducing the risk of delamination and cracking during thermal processes. Dummy bump structures 488D may be positioned in key areas to provide additional mechanical support, particularly in regions prone to delamination. The redistribution wiring interconnects 480 may include patterns designed to reduce moisture stress, with configurations that limit the contact between the redistribution dielectric layers 460 and moisture-absorbing materials. The openings 461 in a topmost redistribution dielectric layer 460, in embodiments that include them, expose segments of the redistribution wiring interconnects 480 during manufacturing, and may be used as degassing pathways, allowing moisture to escape during the heating process. The various embodiments of the present disclosure improve the structural integrity of a composite package 800, increase manufacturing yield for the composite package 800, and increase long-term reliability of the composite package 800 in applications where thermal and moisture stress generate adverse effects.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph or in different paragraphs, a Markush group including a listing of the two or more elements may also be impliedly disclosed. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming an interposer comprising first redistribution wiring interconnects formed within first redistribution dielectric layers;
forming first bump structures and dummy bump structures on a respective one of the first redistribution wiring interconnects; and
attaching at least one semiconductor die comprising a respective array of second bump structures to a respective subset of the first bump structures of the interposer; and
forming a dielectric layer between the dummy bump structures and the semiconductor die.

2. The method of claim 1, further comprising attaching solder material portions to the first bump structures, wherein the second bump structures are bonded to the first bump structures through the solder material portions.

3. The method of claim 2, further comprising attaching dummy solder material portions to the dummy bump structures, wherein the dummy bump structures do not contact the at least one semiconductor die after the at least one semiconductor die is bonded to the interposer.

4. The method of claim 3, further comprising applying an underfill material between the interposer and the at least one semiconductor die around the solder material portions and the dummy solder material portions to form an underfill material portion, wherein all surfaces of each of the dummy solder material portions are contacted by a combination of the underfill material portion and a respective one of the dummy bump structures.

5. The method of claim 1, wherein a first subset of the dummy bump structures is formed such that each dummy bump structure within the first subset of the dummy bump structures is electrically connected to a respective first bump structure selected from the first bump structures of the interposer.

6. The method of claim 5, wherein a second subset of the dummy bump structures is formed such that each dummy bump structure within the second subset of the dummy bump structures is electrically disconnected from each of the first bump structures of the interposer.

7. The method of claim 1, further comprising forming openings vertically extending downward from a topmost surface of the first redistribution dielectric layers such that top surface segments of a subset of the first redistribution wiring interconnects are physically exposed underneath the openings.

8. The method of claim 1, wherein:
the at least one semiconductor die is attached to the interposer using at least one array of solder material portions;
the method comprises applying an underfill material between the interposer and the at least one semiconductor die around the at least one array of solder material portions to form an underfill material portion; and
the underfill material portion fills openings that extend downward from a topmost surface of the first redistribution dielectric layers.

9. The method of claim 1, wherein a subset of the first redistribution wiring interconnects is formed with at least one element which is selected from:
a first element comprising multiple interconnected metal line segments such that adjoined pairs of line segments have different horizontal propagation directions that differ by a respective acute angle;
a second element comprising a one-dimensional array of straight metal lines having a uniform width that is less than a width of each of the first bump structures and having a uniform spacing that is less than the width of each of the first bump structures; and
a third element comprising a two-dimensional array of metal pads each having a width that is not greater than 250% of a width of each of the first bump structures and each having a length that is not greater than 250% of the width of each of the first bump structures.

10. The method of claim 1, wherein:
a subset of the first redistribution wiring interconnects comprises a respective vertically-extending through hole therein; and
the respective vertically-extending through hole is filled with a dielectric material of one of the first redistribution dielectric layers during formation of the interposer.

11. A method of forming a semiconductor structure, comprising:
forming an interposer comprising first redistribution wiring interconnects formed within first redistribution dielectric layers;
forming openings vertically extending downward from a topmost surface of the first redistribution dielectric layers such that top surface segments of a subset of the first redistribution wiring interconnects are physically exposed underneath the openings; and
attaching at least one semiconductor die to the interposer.

12. The method of claim 11, further comprising forming first bump structures on the first redistribution wiring interconnects, wherein the top surface segments of the subset of the first redistribution wiring interconnects are exposed after formation of the first bump structures.

13. The method of claim 12, wherein:
each of the at least one semiconductor die comprises a respective array of second bump structures that is bonded to a respective subset of the first bump structures of the interposer while attaching the at least one semiconductor die to the interposer;
the method comprises applying an underfill material between the interposer and the at least one semiconductor die to form an underfill material portion; and
the underfill material portion fills the openings that vertically extend downward from the topmost surface of the first redistribution dielectric layers.

14. The method of claim 12, further comprising forming dummy bump structures on the subset of the first redistribution wiring interconnects, wherein the dummy bump structures are not bonded to any of the at least one semiconductor die after the at least one semiconductor die is attached to the interposer.

15. The method of claim 14, wherein the dummy bump structures are electrically connected to a respective one of the die-side bump structures.

16. A semiconductor structure comprising an assembly of an interposer and a semiconductor die, wherein:
the interposer comprises first redistribution wiring interconnects embedded within first redistribution dielectric layers, and first bump structures and dummy bump structures contacting a respective one of the first redistribution wiring interconnects;
the semiconductor die comprises a respective array of second bump structures that is bonded to a respective subset of the first bump structures (move to dependent claim); and
a dielectric material is formed between the dummy bump structures and the semiconductor die.

17. The semiconductor structure of claim 16, wherein each of the dummy bump structures is contacted by a respective dummy solder material portion.

18. The semiconductor structure of claim 17, wherein the dummy solder material portions are not in direct contact with any of the at least one semiconductor die.

19. The semiconductor structure of claim 16, wherein the dummy bump structures have an areal overlap with the at least one semiconductor die in a plan view.

20. The semiconductor structure of claim 16, wherein:
a top surface of the first redistribution dielectric layers comprises indentations;
each array of solder material portions is laterally surrounded by an underfill material portion; and
the underfill material portion comprises downward protrusions that fill the indentations in the top surface of the first redistribution dielectric layers.
